(19) United States
(12) Patent Application Publication
(10) Pub. No.: US 2004/0263260 A1
(43) Pub. Date: Dec. 30, 2004

(54) Device and method of wide-range tuning of oscillators

(76) Inventors: Ashoke Ravi, Hillsboro, OR (US); Krishnamurthy Soumyanath, Portland, OR (US)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/608,142

(22) Filed: Jun. 30, 2003

(51) Int. Cl. H03L 7/00

(52) U.S. Cl. 331/16

(57) ABSTRACT

Briefly, devices and methods for wide-range tuning of oscillators which may be used, for example, in a Complementary Metal-Oxide Semiconductor (CMOS) process. An oscillator in accordance with an exemplary embodiment of the invention may include, for example, a tuner to tune a frequency of the oscillator between a first free-running frequency of a first oscillation tank and a second free-running frequency of a second oscillation tank.

### BACKGROUND OF THE INVENTION

Some conventional Radio Frequency (RF) transceivers incorporate a Voltage Controlled Oscillator (VCO), which needs to be tuned over a wide range of frequencies, for example, to cover entire transmit and receive bands with the same VCO.

Some conventional VCOs use diodes or Metal Oxide Semiconductor (MOS) capacitors as varactors. The tuning range obtained from using these components may be very limited and may require an additional high voltage supply.

### BRIEF DESCRIPTION OF THE DRAWINGS

The subject matter regarded as the invention is particularly pointed out and distinctly claimed in the concluding portion of the specification. The invention, however, both as to organization and method of operation, together with features and advantages thereof, may best be understood by reference to the following detailed description when read with the accompanied drawings in which:

FIG. 1 is a schematic illustration of a wireless communication device incorporating an oscillator in accordance with exemplary embodiments of the invention;

FIG. 2 is a schematic block illustration of an oscillator circuit in accordance with exemplary embodiments of the invention;

FIG. 3 is a schematic illustration of an oscillator circuit using interpolation through current steering in accordance with an exemplary embodiment of the invention; and

FIG. 4 is a schematic illustration of an oscillator circuit using interpolation through current source control in accordance with another exemplary embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, units and/or circuits have not been described in detail so as not to obscure the invention.

It should be understood that embodiments of the invention may be used in a variety of applications. Although the invention is not limited in this respect, embodiments of the invention may be used in many apparatuses, for example, a transmitter, a receiver, a transceiver, a transmitter-receiver, and/or a wireless communication device. Wireless communication devices intended to be included within the scope of the invention include, by way of example only, cellular radio-telephone communication systems, cellular telephones, wireless telephones, cordless telephones, Wireless Local Area Networks (WLAN) and/or devices operating in accordance with the existing 802.11a, 802.11b, 802.11 g, 802.11n and/or future versions of the above standards, Personal Area Networks (PAN), Wireless PAN (WPAN), units and/or devices which are part of the above WLAN and/or PAN and/or WPAN networks, one way and/or two-way radio communication systems, one-way pagers, two-way pagers, Personal Communication Systems (PCS) devices, a Portable Digital Assistant (PDA) device which incorporates a wireless communication device, an ultra wide-band radio device, high-frequency clocks, high-frequency oscillators, high-frequency processors, and the like.

By way of example, types of cellular radio-telephone communication systems intended to be within the scope of the invention include, although not limited to, Direct Sequence—Code Division Multiple Access (DS-CDMA) cellular radio-telephone communication systems, Global System for Mobile Communications (GSM) cellular radio-telephone systems, North American Digital Cellular (NADC) cellular radio-telephone systems, Time Division Multiple Access (TDMA) systems, Extended-TDMA (E-TDMA) cellular radio-telephone systems, Wideband CDMA (WCDMA) systems, General Packet Radio Service (GPRS) systems, Enhanced Data for GSM Evolution (EDGE) systems, 3G systems, 3.5G systems, 4G systems, communication devices using various frequencies and/or range of frequencies for reception and/or transmission, communication devices using 2.4 Gigahertz frequency, communication devices using 5.2 Gigahertz frequency, communication devices using 24 Gigahertz frequency, communication devices using an Industrial Scientific Medical (ISM) band and/or several ISM bands, and other existing and/or future versions of the above.

It is noted that embodiments of the invention may be used in various other apparatuses.

It will be appreciated that the term “oscillator” as used herein may include, for example, an oscillator, an oscillator circuit, an oscillation circuit, an oscillation device, an oscillation unit or circuitry, a device including an oscillation circuit, an oscillator tuning circuit, an oscillator tuning device, and/or any suitable circuit, circuitry, sub-circuit, component, device and/or unit, or any suitable combination thereof, which may produce, provide, create, change, modify, tune and/or fine-tune oscillation.

Exemplary embodiments of the invention provide circuits and methods for wide-range tuning of oscillators. For example, some embodiments of the invention provide a circuit for wide-range tuning of an oscillator, which may be used, for example, in conjunction with high performance, low power, Radio Frequency (RF) transceivers that use a low cost, low voltage, digital single-supply Complementary Metal-Oxide Semiconductor (CMOS) process.

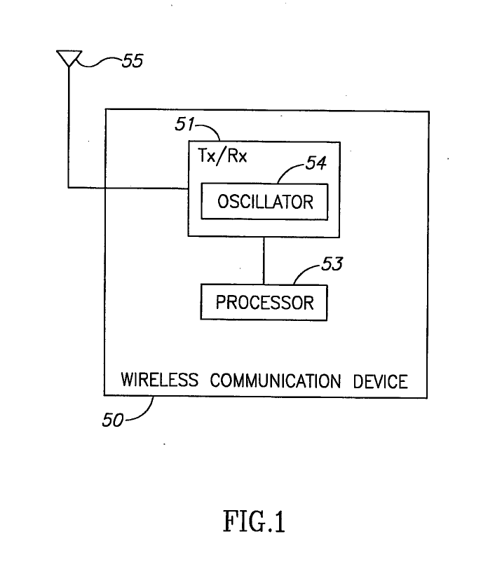

FIG. 1 schematically illustrates a wireless communication device 50 incorporating an oscillator 54 in accordance with some embodiments of the invention. In exemplary embodiments of the invention, wireless communication device 50 may further include a transceiver 51, a processor 53, and an antenna 55.

Processor 53 may include, for example, a Central Processing Unit (CPU), a Digital Signal Processor (DSP), a chip, a microchip, or any other suitable multi-purpose or specific processor or micro-processor.

Antenna 55 may include an internal and/or external antenna, for example, a dipole antenna and/or a Radio Frequency (RF) antenna, or any other type of antenna suitable for sending and receiving signals to enable device 50 to communicate with a desired communication network.

Transceiver 51 may be implemented, for example, using one or more units performing separate or integrated functions, for example, in the form of separate transmitter and receiver units or in the form of a single transceiver unit or a single transmitter-receiver unit. Transceiver 51 may include oscillator 54, or several oscillators or oscillating circuits, e.g., similar to oscillator 54.

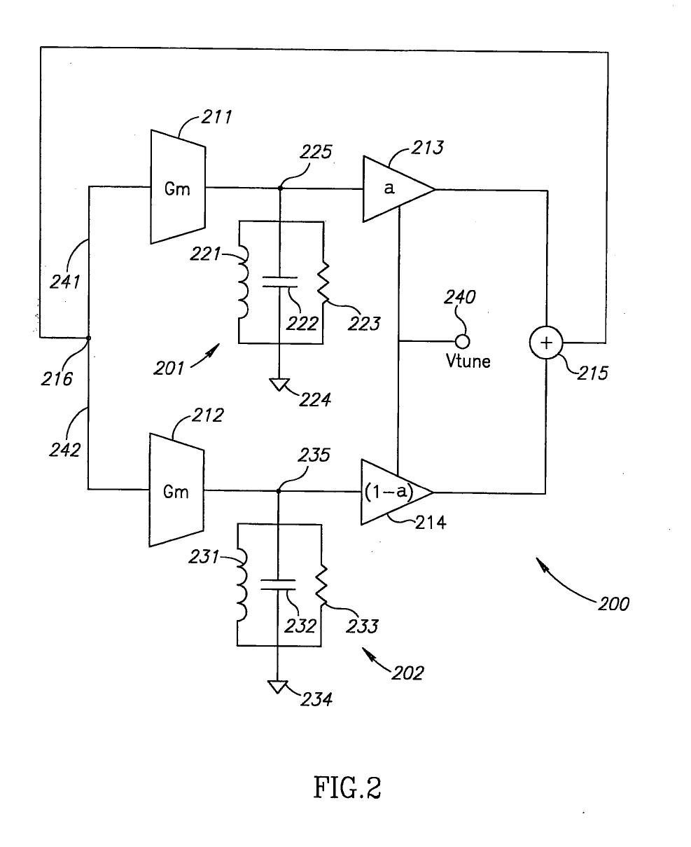

Oscillator 54 may include an oscillator and/or an oscillating circuit in accordance with embodiments of the invention, for example, as described below with reference to the exemplary embodiments of FIGS. 2 to 4.

FIG. 2 schematically illustrates an oscillator circuit 200 in accordance, with some exemplary embodiments of the invention. Oscillator circuit 200 may include a path 241 and a path 242, which may be connected in parallel between a node 216 and an adder 215.

Path 241 may include a transconductor 211, an amplifier 213, and an oscillation tank 201 connected to a node 225. Tank 201 may include three parallel branches, namely, an inductor 221, a capacitor 222, and a resistor 223. The three branches may be connected in parallel between node 225 and ground 224. Tank 201 may have a first free-running (e.g., natural or self-resonant) frequency, which may be selected in accordance with specific implementations and design requirements.

Path 242 may include a transconductor 212, an amplifier 214, and an oscillation tank 202 connected to a node 223. Tank 202 may include three parallel branches, namely, an inductor 231, a capacitor 232, and a resistor 233. The three branches may be connected in parallel between node 225 and ground 224. Tank 202 may have a second free-running frequency, which may be selected in accordance with specific implementations and design requirements.

In accordance with exemplary embodiments of the invention, the first free-running frequency of tank 201 may be different, e.g., higher or lower than, the second free-running frequency of tank 202.

During operation of circuit 200, amplifiers 213 and 214 may be controlled and/or tuned to produce desired respective gains. In an exemplary embodiment, the gain produced by amplifier 213 may complement the gain produced by amplifier 214, and vice versa. For example, amplifier 213 may produce a gain of a and amplifier 214 may produce a gain of c-a, such that the total gain, c, produced by the combination of amplifiers 213 and 214 may be substantially constant. In exemplary embodiments of the invention, c is equal to one, i.e., the gains of amplifiers 213 and 214 may be a and 1-a, respectively, and the effective combined gain of branches paths 241 and 242 is equal to substantially one, whereby the over-all gain of oscillation circuit 200 remains substantially unchanged.

In some embodiments, a tuning voltage may be used, for example, at a node 240, to tune the gains of amplifiers 213 and 214. In an exemplary embodiment, such tuning may be performed substantially continuously and/or substantially linearly. By tuning the gains of amplifiers 213 and 214 of paths 241 and 242, the relative (e.g., weighted) contributions of paths 241 and 242 may be substantially continuously controlled to produce desired weights, e.g., a and 1-a, respectively.

It is noted that amplifiers 213 and 214, and optionally node 240 which receives a tuning voltage, may be part of a circuit implementation of a scaler or a scaling unit in accordance with embodiments of the invention. Such implementations of the scaler or scaling unit may include other suitable components of circuit 200. Other implementations of a scaler of a scaling unit are also within the scope of embodiments of the invention.

The weighted contributions of path 241 and path 242 may be added, for example, using adder 215. As a result, circuit 200 may oscillate at an oscillation frequency, in between the first free-running frequency of tank 201 and the second free-running frequency of tank 202. In an exemplary embodiment, the oscillation frequency of circuit 200 may be related to, e.g., substantially proportional to, a linear weighted average of the currents running through paths 241 and 242.

It will be appreciated by persons skilled in the art that, in some embodiments, Barkhausen criterion may be satisfied at a certain intermediate frequency between the free-running frequencies of tank 201 and tank 202, and that circuit 200 may be tuned to oscillate at said intermediate frequency.

It is noted that adder 215, amplifiers 213 and 214, and optionally node 240 which receives a tuning voltage, may be part of a circuit implementation of a tuner or a tuning unit in accordance with embodiments of the invention. Such implementations of the tuner or tuning unit may include other suitable components of circuit 200. Other implementations of a tuner of a tuning unit are also within the scope of embodiments of the invention.

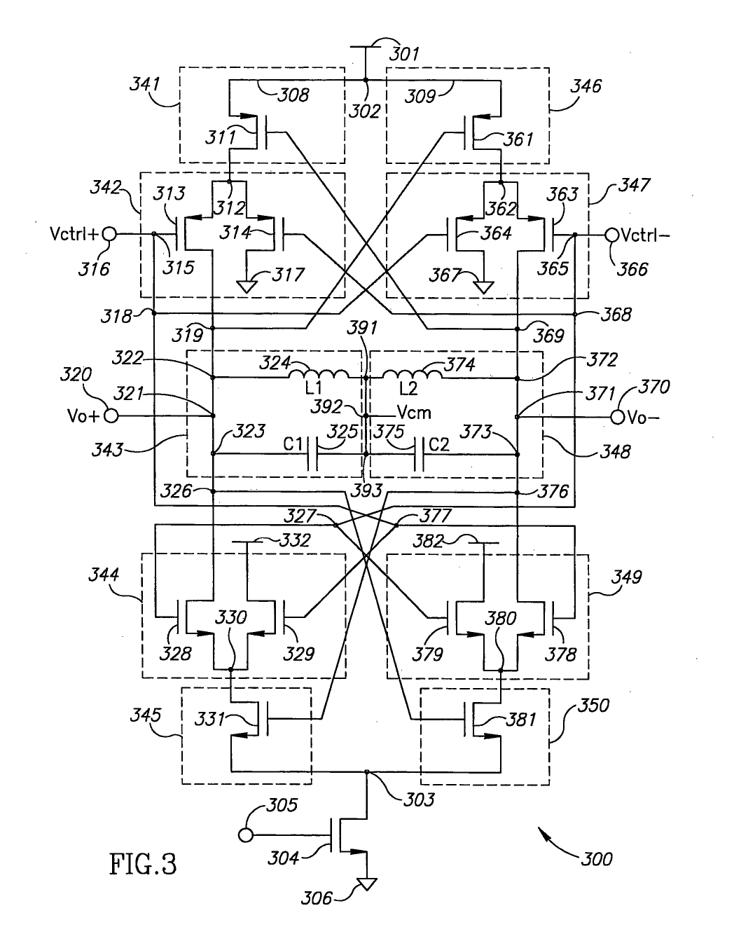

FIG. 3 schematically illustrates an oscillator circuit 300, which uses interpolation through current steering in accordance with an exemplary embodiment of the invention. Oscillator circuit 300 may include two parallel paths, 308 and 309, respectively, connected between a node 302 and a node 303.

Node 302 may receive electrical current from a supply voltage 301. A node 303 may be connected to a drain terminal of a transistor 304. A source terminal of transistor 304 may be connected to a sink 306. A gate terminal of transistor 304 may be connected to a node 305, which may be provided with bias for a current source.

Node 302 may be connected to a source terminal of a transistor 311. A drain terminal of transistor 311 may be connected to a node 312, and a gate terminal of transistor 311 may be connected to a node 369. Node 312 may be connected to a source terminal of a transistor 313, and to a source terminal of a transistor 314. A drain terminal of transistor 314 may be connected to a sink 317, and a gate terminal of transistor 314 may be connected to a node 368. A drain terminal of transistor 313 may be connected to a node 319, and a gate terminal of transistor 313 may be connected to a node 315.

Node 315 may be connected to a node 316, which may have a positive control voltage. Node 315 may be connected to node 318, which may be connected to a node 377 and to a gate terminal of a transistor 361. Node 319 may be connected to a node 322 and to a gate terminal of transistor 361. Node 322 may be connected to a node 321 and to a node 323. Node 321 may be connected to a node 320, which may have a positive output voltage. Node 322 may be connected to an inductor 324, which may be connected to a node 391. Node 323 may be connected to a capacitor 325, which may be connected to a node 393. Node 393 may be connected to a node 392, which may be connected to node 391. Node 392 may have a common mode voltage.

Node 323 may be connected to a node 326. Node 326 may be connected to a gate terminal of a transistor 381, and to a drain terminal of a transistor 328. A gate terminal of transistor 328 may be connected to a node 327, and a source terminal of transistor 328 may be connected to a node 330. Node 330 may be connected to a source terminal of a transistor 329. A drain terminal of transistor 329 may be connected to a voltage supply 332. A gate terminal of transistor 329 may be connected to node 377, which may be connected to a gate terminal of a transistor 378. Node 330 may be connected to a drain terminal of a transistor 331. A gate terminal of transistor 331 may be connected to a node 376, and a source terminal of transistor 331 may be connected to node 303.

Node 302 may be connected to a source terminal of transistor 361. A drain terminal of transistor 361 may be connected to a node 362, and a gate terminal of transistor 361 may be connected to node 319. Node 362 may be connected to a source terminal of a transistor 363, and to a source terminal of a transistor 364. A drain terminal of transistor 364 may be connected to a sink 367, and a gate terminal of transistor 364 may be connected to node 318. A drain terminal of transistor 363 may be connected to a node 369, and a gate terminal of transistor 363 may be connected to a node 365.

Node 365 may be connected to a node 366, which may have a negative control voltage. Node 365 may be connected to node 368, which may be connected to node 327 and to a gate terminal of transistor 311. Node 369 may be connected to a node 372 and to a gate terminal of transistor 311. Node 372 may be connected to a node 371 and to a node 373. Node 371 may be connected to a node 370, which may have a negative output voltage. Node 372 may be connected to an inductor 374, which may be connected to node 391. Node 373 may be connected to a capacitor 375, which may be connected to node 393.

Node 373 may be connected to node 376. Node 376 may be connected to a gate terminal of transistor 331, and to a drain terminal of transistor 378. A gate terminal of transistor 378 may be connected to node 377, and a source terminal of transistor 378 may be connected to a node 380. Node 380 may be connected to a source terminal of a transistor 379. A drain terminal of transistor 379 may be connected to a voltage supply 382. A gate terminal of transistor 379 may be connected to node 327, which may be connected to a gate terminal of transistor 328. Node 380 may be connected to a drain terminal of transistor 381. A gate terminal of transistor 381 may be connected to node 326, and a source terminal of transistor 381 may be connected to node 303.

Oscillator circuit 300 of FIG. 300 may be an exemplary implementation of oscillator circuit 200 of FIG. 2, such that various groups of components in oscillator circuit 300 may perform operations and/or functions of a corresponding unit in oscillator circuit 200. For example, group 341 and group 345 may correspond to transconductor 211; group 346 and group 350 may correspond to transconductor 212; group 342 and group 344 may correspond to amplifier 213; group 347 and group 349 may correspond to amplifier 214; group 343 may correspond to tank 201, and group 348 may correspond to tank 202.

The current steering approach of oscillator 300 may be used to add and/or scale the gains of path 308 and path 309. In some embodiments, this may be implemented using a single stack.

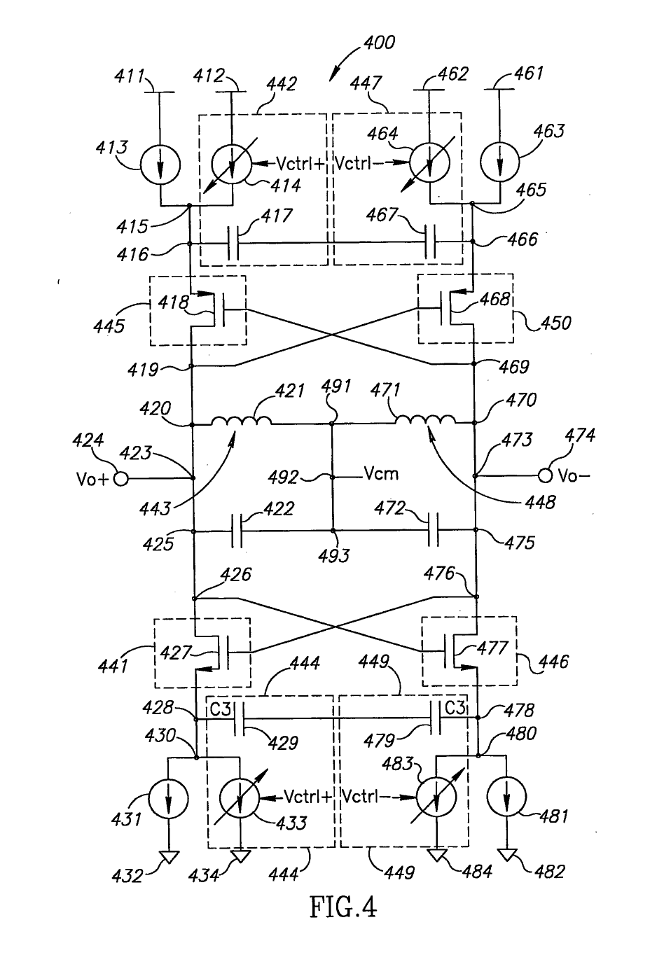

FIG. 4 schematically illustrates an oscillator circuit 400 using interpolation through current source control in accordance with an exemplary embodiment of the invention. Oscillator circuit 400 may include a path 401 and a path 402.

A voltage supply 411 may provide a fixed current 413 to a node 415. A voltage supply 412 may provide a tunable current 414 to node 415; tunable current 414 may be tuned, for example, using a negative control voltage. Node 415 may be connected to a node 416. Node 416 may be connected to a capacitor 417, which may be connected to a capacitor 467. Node 416 may be connected to a source terminal of a transistor 418. A gate terminal of transistor 418 may be connected to a node 469. A drain terminal of transistor 418 may be connected to a node 419, which may be connected to a node 420. Node 420 may be connected to an inductor 421, which may be connected to a node 491. Node 420 may be connected to a node 423, which may be connected to a node 424 and to a node 425. Node 424 may have a positive output voltage. Node 425 may be connected to a capacitor 422, which may be connected to a node 493. Node 493 may be connected to a node 492, which may be connected to node 491. Node 492 may have a common mode voltage.

Node 425 may be connected to a node 426. Node 426 may be connected to a gate terminal of a transistor 477, and to a drain terminal of a transistor 427. A source terminal of transistor 427 may be connected to a node 428. Node 428 may be connected to a capacitor 429, which may be connected to a capacitor 479. Node 428 may be connected to a node 430. Node 430 may provide a fixed current 431 to a sink 432. Node 430 may provide a tunable current 433 to a sink 434; tunable current 433 may be tuned, for example, using a positive control voltage.

A voltage supply 461 may provide a fixed current 463 to a node 465. A voltage supply 462 may provide a tunable current 464 to node 465; tunable current 464 may be tuned, for example, using a positive control voltage. Node 465 may be connected to a node 466. Node 466 may be connected to capacitor 467, which may be connected to capacitor 417. Node 466 may be connected to a source terminal of a transistor 468. A gate terminal of transistor 468 may be connected to node 419. A drain terminal of transistor 468 may be connected to node 469, which may be connected to a node 470. Node 470 may be connected to an inductor 471, which may be connected to node 491. Node 470 may be connected to a node 473, which may be connected to a node 474 and to a node 475. Node 474 may have a negative output voltage. Node 475 may be connected to a capacitor 472, which may be connected to node 493. Node 493 may be connected to node 492, which may be connected to node 491.

Node 475 may be connected to node 476. Node 476 may be connected to a gate terminal of transistor 427, and to a drain terminal of transistor 477. A source terminal of transistor 477 may be connected to a node 478. Node 478 may be connected to capacitor 479, which may be connected to capacitor 429. Node 478 may be connected to a node 480. Node 480 may provide a fixed current 481 to a sink 482. Node 480 may provide a tunable current 483 to a sink 484; tunable current 483 may be tuned, for example, using a negative control voltage.

Oscillator circuit 400 of FIG. 400 may be another exemplary implementation of oscillator circuit 200 of FIG. 2, such that various groups of components in oscillator circuit 400 may perform operations and/or functions of a corresponding unit in oscillator circuit 200. For example, group 441 and group 445 may correspond to transconductor 211; group 446 and group 450 may correspond to transconductor 212; group 442 and group 444 may correspond to amplifier 213; group 447 and group 449 may correspond to amplifier 214; group 443 may correspond to tank 201, and group 448 may correspond to tank 202.

It is noted that in some embodiments, oscillator circuit 300 of FIG. 3 and/or oscillator circuit 400 of FIG. 4 may optionally include one or more capacitive dividers (not shown). A capacitive divider may be used, for example, between gate terminal of transistor 311 and node 369, between gate terminal of transistor 361 and node 319, and/or in other cross-connections of the two paths of oscillator circuit 300 or oscillator circuit 400. Similarly, one or more capacitive dividers may be used within amplifier 213 and/or amplifier 214 in oscillator circuit 200 of FIG. 2. Using such capacitor dividers may allow, for example, more accurate tuning and/or fine-tuning of oscillator circuits 200, 300 or 400. It is noted that in some embodiments using a capacitive divider, transistors comprising a transconductor unit may be suitably biased, for example, to a mid-rail voltage or through a self-bias network.

It is noted that two, fully differential, oscillators may be used in accordance with embodiments of the invention.

In some oscillators in accordance with embodiments of the invention, Metal-Insulator-Metal (MIM) capacitors may be used. Additionally or alternatively, in some oscillators in accordance with embodiments of the invention, vertical stacked metal-metal capacitors may be used. Additionally or alternatively, in some oscillators in accordance with embodiments of the invention, suitable Metal Oxide Semiconductor (MOS) devices may be used, for example, MOS devices confined to operate only in either the inversion region or the accumulation region. Some embodiments of the invention may allow, for example, fine tuning of one extremity and/or two extremities of the frequency range; in some implementations, such fine tuning may, for example, compensate for mismatch and/or process variations.

Further exemplary embodiments of the invention provide methods of tuned oscillation, for example, including the following operations, some or all of which may be performed using the circuits described above or circuits with similar structure and/or functionality.

In exemplary methods of tuned oscillation according to embodiments of the invention, a frequency of an oscillator circuit may be tuned to a value between a first free-running frequency of a first oscillation tank and a second free-running frequency of a second oscillation tank. In an exemplary embodiment, this may be performed, for example, by producing a first gain in a first circuit path associated with the first oscillating tank and producing a second gain in a second circuit path associated with the second oscillating tank.

In some exemplary embodiments, the first and second gains may be complementary. In some exemplary embodiments, the sum of the first and second gains may be substantially constant. In some exemplary embodiments, the sum of the first and second gains may be substantially one.

In exemplary embodiments of the invention, first and second signal components passing through the first and second circuit paths, respectively, may be added. Depending on the relative gains of the first and second signal components, the oscillator circuit may oscillate at a frequency between the first and second free-running frequencies.

In an exemplary embodiment, producing the first and second gains may include controlling relative values, e.g., scaling factors, of the first and second gains. By continuously varying the scaling factors, the frequency produced by the circuit may be continuously tuned to substantially any value between the first and second free-running frequencies of the first and second oscillation tanks, respectively.

In some embodiments, the above operations may be repeated, for example, continuously or substantially continuously. Additionally or alternatively, other operations and/or series of operations and/or methods may be used in accordance with embodiments of the invention.

Some embodiments of the invention may be implemented by software, by hardware, or by any combination of software and/or hardware as may be suitable for specific applications or in accordance with specific design requirements. Embodiments of the invention may include units and/or sub-units, which may be separate of each other or combined together, in whole or in part, and may be implemented using specific, multi-purpose or general processors, or devices as are known in the art. Some embodiments of the invention may include buffers, registers, storage units and/or memory units, for temporary or long-term storage of data or in order to facilitate the operation of a specific embodiment.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. An apparatus comprising:
a tuner to tune an oscillation frequency of an oscillator to a value between a first free-running frequency of a first oscillation tank and a second free-running frequency of a second oscillation tank.

2. The apparatus of claim 1, wherein the tuner comprises a scaler to produce a first gain in a first path of the oscillator associated with the first oscillation tank and to produce a second gain in a second path of said oscillator associated with the second oscillation tank.

3. The apparatus of claim 2, wherein the tuner comprises an adder to add first and second signal components passing through said first and second paths, respectively.

4. The apparatus of claim 2, wherein the first and second gains are complementary.

5. The apparatus of claim 4, wherein a sum of said first and second gains is substantially constant.

6. The apparatus of claim 5, wherein the sum of said first and second gains is substantially equal to one.

7. The apparatus of claim 2, wherein the tuner is able to control the relative values of said first and second gains.

8. The apparatus of claim 2, wherein the scaler comprises first and second amplifiers on said first and second paths, respectively, to provide said first and second gains, respectively.

9. The apparatus of claim 2, wherein the scaler is able to control first and second voltages applied to said first and second amplifiers, respectively.

10. The apparatus of claim 3, wherein the first path comprises a first transconductor and wherein the second path comprises a second transconductor.

11. A wireless communication device comprising:
a dipole antenna to send and receive wireless communication signals; and
an oscillator comprising a tuner to tune an oscillation frequency of said oscillator to a value between a first free-running frequency of a first oscillation tank and a second free-running frequency of a second oscillation tank.

12. The wireless communication device of claim 11, wherein the tuner comprises a scaler to produce a first gain in a first path of said oscillator associated with the first oscillation tank and to produce a second gain in a second path of said oscillator associated with the second oscillation tank.

13. The wireless communication device of claim 12, wherein the tuner comprises an adder to add first and second signal components passing through said first and second paths, respectively.

14. The wireless communication device of claim 12, wherein the first and second gains are complementary.

15. The wireless communication device of claim 14, wherein a sum of said first and second gains is substantially constant.

16. The wireless communication device of claim 15, wherein the sum of said first and second gains is substantially equal to one.

17. The wireless communication device of claim 12, wherein the tuner is able to control the relative values of said first and second gains.

18. The wireless communication device of claim 12, wherein the scaler comprises first and second amplifiers on said first and second paths, respectively, to provide said first and second gains, respectively.

19. The wireless communication device of claim 12, wherein the scaler is able to control first and second voltages applied to said first and second amplifiers, respectively.

20. The wireless communication device of claim 13, wherein the first path comprises a first transconductor and wherein the second path comprises a second transconductor.

21. A method comprising:
tuning a frequency of an oscillator to a value between a first free-running frequency of a first oscillation tank and a second free-running frequency of a second oscillation tank.

22. The method of claim 21, wherein tuning the frequency comprises:
producing a first gain in a first path associated with the first oscillation tank; and
producing a second gain in a second path associated with the second oscillation tank.

23. The method of claim 22, wherein tuning the frequency comprises adding first and second signal components passing through said first and second paths, respectively.

24. The method of claim 22, wherein producing said first and second gains comprises producing first and second complementary gains.

25. The method of claim 24, wherein a sum of said first and second gains is substantially constant.

26. The method of claim 25, wherein the sum of said first and second gains is substantially one.

27. The method of claim 22, wherein tuning the frequency comprises controlling relative values of said first and second gains.
